(19) United States
(12) Patent Application Publication
(10) Pub. No.: US 2015/0311190 A1
(43) Pub. Date: Oct. 29, 2015

(54) LIGHT EMITTING DIODE PACKAGE STRUCTURE

(71) Applicant: Genesis Photonics Inc., Tainan City (TW)

(72) Inventors: Meng-Ting Tsai, Tainan City (TW); Hao-Chung Lee, Tainan City (TW); Yu-Feng Lin, Tainan City (TW)

(21) Appl. No.: 14/697,641

(22) Filed: Apr. 28, 2015

(30) Foreign Application Priority Data
Apr. 29, 2014 (TW) 103207443

(51) Int. Cl. H01L 27/02; H01L 27/15; H01L 33/48; H01L 29/866; H01L 33/62; H01L 33/60

(52) U.S. Cl. CPC H01L 27/0248; H01L 33/62; H01L 33/60; H01L 33/48; H01L 29/866; H01L 27/156

(57) ABSTRACT

A light emitting diode (LED) package structure including a carrier substrate, a LED and an electrostatic protection device is provided. The carrier substrate includes two leadframes separated from each other and a reflective member. The reflective member encapsulates the leadframes and exposes a carrier surface of each of the leadframes. The reflective member has a cavity, and a bottom surface of the cavity is aligned with the carrier surface of each of the leadframes. The LED is disposed inside the cavity and bridges the leadframes. The electrostatic protection device is disposed inside the cavity and bridges the leadframes. The LED is connected in anti-parallel to the electrostatic protection device.

### CROSS-REFERENCE TO RELATED APPLICATION

This application claims the priority benefit of Taiwan application serial no. 103207443, filed on Apr. 29, 2014. The entirety of the above-mentioned patent application is hereby incorporated by reference herein and made a part of this specification.

### BACKGROUND OF THE INVENTION

1. Field of the Invention

The invention relates to a package structure, and particularly relates to a light emitting diode package structure.

2. Description of Related Art

Since light emitting diode (LED) has advantages of long service life, small volume, high shock resistance, low heat generation, and low power consumption, etc., it is widely applied to serve as indicators and light sources in home appliances and various equipment. Although the LED has the aforementioned advantages, it is liable to be damaged due to abnormal voltage or electrostatic discharge (ESD). In a conventional method, in order to avoid damaging the LED due to the abnormal voltage or ESD, the LED and an electrostatic protection device, for example, a Zener diode are both disposed on a same carrier substrate, and the LED and the Zener diode are connected inversely through an electrode, so as to avoid damaging the LED due to the abnormal voltage or ESD.

However, sizes of a long side and a short side of two leadframes on the carrier substrate are close (for example, a ratio between the long side and the short side is 1.2:1), so that only the LED can bridge on the two leadframes at most, and the electrostatic protection device is disposed on one of the leadframes and is connected to another leadframe through a metal wire. However, such metal wire connection probably leads to an open circuit due to unstable connection between the Zener diode and the metal wire, and the Zener diode cannot implement a voltage regulation effect.

### SUMMARY OF THE INVENTION

The invention is directed to a light emitting diode (LED) package structure, which has good light emitting efficiency and configuration.

The invention provides a light emitting diode (LED) package structure, which includes a carrier substrate, a LED and an electrostatic protection device. The carrier substrate includes two leadframes separated from each other and a reflective member. The reflective member encapsulates the leadframes and exposes a carrier surface of each of the leadframes. The reflective member has a cavity, and a bottom surface of the cavity is aligned with the carrier surface of each of the leadframes. The LED is disposed inside the cavity and electrically bridges the leadframes. The electrostatic protection device is disposed inside the cavity and electrically bridges the leadframes. The LED is connected in anti-parallel to the electrostatic protection device.

In an embodiment of the invention, a surface area of an upper surface of the leadframes is greater than a surface area of the bottom surface of the cavity.

In an embodiment of the invention, the leadframes are separated from each other and spaced by a horizontal spacing distance, a contour of the carrier surface of each of the leadframes is a rectangle, and the horizontal spacing distance is smaller than a short side of the carrier surface.

In an embodiment of the invention, a contour of the carrier surface of each of the leadframes is a rectangle, and a vertical distance between one side of the LED and a short side of the corresponding carrier surface is 1.2-10 times of a width of the electrostatic protection device.

In an embodiment of the invention, a contour of the carrier surface of each of the leadframes is a rectangle, and a vertical distance between one side of the LED and a short side of the corresponding carrier surface is between 0.3 cm and 1 cm.

In an embodiment of the invention, a contour of the carrier surface of each of the leadframes is a rectangle, and an aspect ratio of the carrier surface of each of the leadframes is between 2 and 5.

In an embodiment of the invention, a contour of the carrier surface of each of the leadframes is a rectangle, and four corners of the carrier surface are right angles or rounded angles.

In an embodiment of the invention, the cavity has an opening, and the cavity is tapered from the opening towards the bottom surface.

In an embodiment of the invention, the LED and the leadframes of the carrier substrate are electrically connected through eutectic bonding.

In an embodiment of the invention, the LED is a flip chip LED.

In an embodiment of the invention, the electrostatic protection device is a Zener diode.

In an embodiment of the invention, the electrostatic protection device and the leadframes of the carrier substrate are electrically connected through eutectic bonding.

In an embodiment of the invention, the leadframes are symmetrically arranged.

According to the above description, since the carrier substrate of the invention has the reflective member, the light emitted by the LED is reflected by the reflective member, so as to achieve a good light emitting efficiency of the LED package structure of the invention. Moreover, based on the design of the leadframes of the invention, the LED and the electrostatic protection device both bridge the leadframes of the carrier substrate and are connected in anti-parallel, so that the problem of the conventional technique that the Zener diode cannot implement a voltage regulation effect as the connection between the Zener diode and the metal wire is unstable to cause an open circuit is avoided. Namely, the LED package structure of the invention has better structural reliability and configuration space, and the LED is protected by an anti electrostatic protection function of the electrostatic protection device, so as to increase a service life of the LED package structure.

Several exemplary embodiments accompanied with figures are described in detail below to further describe the invention in details.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a light emitting diode (LED) package structure according to an embodiment of the invention.

FIG. 2 is a cross-sectional view of FIG. 1 along a line A-A.

### DESCRIPTION OF EMBODIMENTS

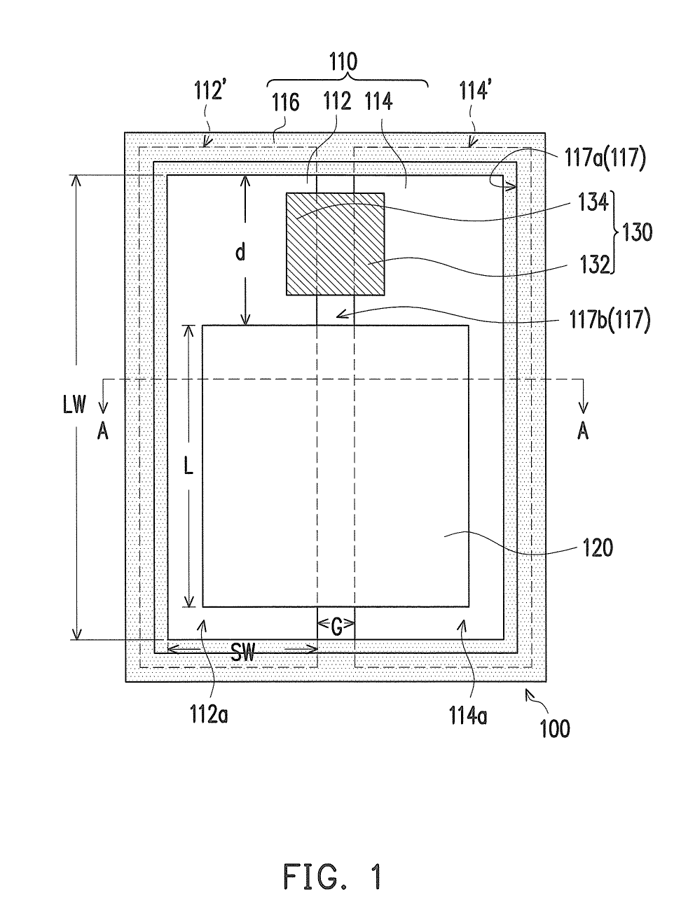

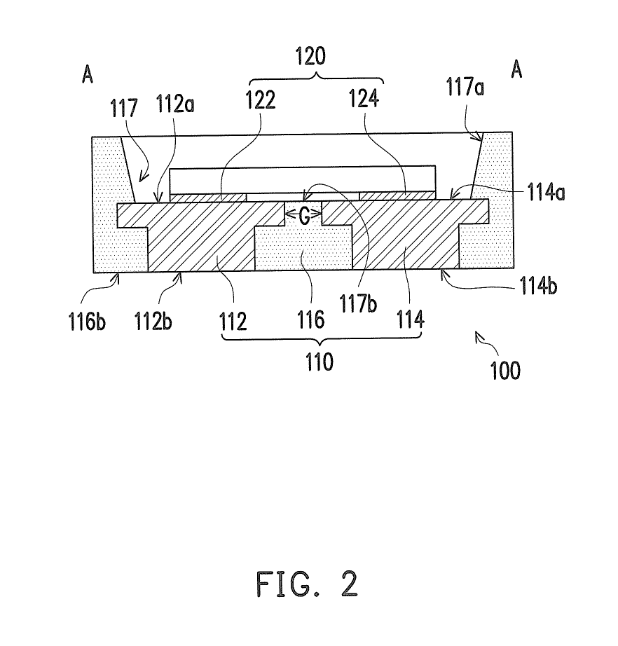

FIG. 1 is a top view of a light emitting diode (LED) package structure according to an embodiment of the invention. FIG. 2 is a cross-sectional view of FIG. 1 along a line A-A. Referring to FIG. 1 and FIG. 2, in the present embodiment, the LED package structure 100 includes a carrier substrate 110, a LED 120 and an electrostatic protection device 130. The carrier substrate 110 includes two leadframes 112, 114 separated from each other and a reflective member 116. The leadframes 112, 114 respectively have upper surfaces 112′, 114′, and the reflective member 116 encapsulates the leadframes 112, 114 and exposes a carrier surface 112a (or 114a) of each of the leadframes 112 (or 114). In other words, the carrier surface 112a (or 114a) is a surface that is not covered by the reflective member 116, so that a surface area of the carrier surface 112a (or 114a) is substantially smaller than a surface area of the upper surface 112′ (or 114′). The reflective member 116 has a cavity 117, and a bottom surface 117b of the cavity 117 is aligned with the carrier surface 112a (or 114a) of each of the leadframes 112 (or 114). The LED 120 is disposed inside the cavity 117 and electrically bridges the leadframes 112, 114. The electrostatic protection device 130 is disposed inside the cavity 117 and electrically bridges the leadframes 112, 114. The LED 120 is connected in anti-parallel to the electrostatic protection device 130.

In detail, the leadframes 112, 114 of the carrier substrate 110 of the present embodiment respectively have different electrical properties, for example, one is positively charged, and another one is negatively charged, where a material of the leadframes 112, 114 is, for example, metal or a conductive material. As shown in FIG. 1, the surface area of the upper surfaces 112′, 114′ of the leadframes 112, 114 is far greater than a surface area of the bottom surface 117b of the cavity 117. Particularly, the leadframes 112, 114 are separated from each other and spaced by a horizontal spacing distance G, where the leadframes 112, 114 expose a part of the bottom surface 117b of the cavity 117. Moreover, a contour of the carrier surface 112a (or 114a) of each of the leadframes 112 (or 114) is embodied by a rectangle, and the horizontal spacing distance G is smaller than a short side SW of the carrier surface 112a (or 114a). According to such configuration, not only the LED 120 and the electrostatic protection device 130 are easy to bridge the leadframes 112, 114, a better heat dissipation effect thereof is achieved through the larger area of the leadframes 112, 114. Preferably, the leadframes 112, 114 have symmetrical figures and are symmetrically configured, such that alignment of the LED 120 and the electrostatic protection device 130 is convenient and has no directional restriction. A ratio between a long side LW and the short side SW of the carrier surface 112a (or 114a) of the leadframe 112 (or 114) is between 2 and 5. In other words, a length of the long side LW is 2-5 times greater than that of the short side SW.

Since a size difference between the long side LW and the short side SW of the carrier surfaces 112a, 114a of the leadframes 112, 114 is relatively large, the long side LW of the carrier surfaces 112a, 114a of the leadframes 112, 114 has an enough configuration space to ensure both of the LED 120 and the electrostatic protection device 130 to bridge leadframes 112, 114. In other words, the LED 120 is overlapped with the leadframes 112, 114, and the electrostatic protection device 130 is also overlapped with the leadframes 112, 114. In this way, compared with the conventional technique that the sizes of the long side and the short side are close to each other (for example, the ratio between the long side and the short side is 1.2:1), such that only the LED can bridge on the leadframes, according to the design of the leadframes 112, 114 of the present embodiment, the problem of the conventional technique that the connection between the Zener diode and the metal wire is unstable to cause an open circuit due to usage of the metal wire for connection is avoided, and the LED 120 and the electrostatic protection device 130 of the present embodiment may have a better configuration, and the LED package structure 100 have a better structural reliability. Preferably, a vertical distance d between one side of the LED 120 and the short side SW of the carrier surface 112a (or 114a) of the corresponding leadframe 112 (or 114) is 1.2-10 times of a width of the electrostatic protection device 130. Optimally, the vertical distance d between one side of the LED 120 and the short side SW of the carrier surface 112a (or 114a) of the corresponding leadframe 112 (or 114) is 0.3-1.0 cm. In this way, there is a proper space for placing the electrostatic protection device 130, and a heat accumulation effect caused due to intensive arrangement of the components is avoided, and a heat dissipation effect of the LED package structure 100 is enhanced.

As shown in FIG. 1, a long side L of the LED 120 is substantially parallel to the long side LW of the carrier surface 112a (or 114a) of the leadframe 112 (or 114), and the leadframes 112, 114 are configured in parallel to each other and an extending direction thereof is parallel to the long side L of the LED 120. According to the above configuration, an area of the LED 120 occupies 25% and 60% of the area of the whole carrier substrate 110. Compared to the conventional configuration (the ratio between the long side and the short side of the leadframe is relatively small) that the area of the LED 120 occupies 23% of the area of the whole carrier substrate at most, the light emitting efficiency of a unit area of the present embodiment is obviously enhanced, and the remained space is enough for the electrostatic protection device 130 to bridge on the leadframes 112, 114, so as to make an effective use of the space.

As shown in FIG. 1, a first electrode 122 and a second electrode 124 of the LED 120 of the present embodiment respectively bridge the leadframes 112, 114, and a first electrode 132 and a second electrode 134 of the electrostatic protection device 130 respectively bridge the leadframes 114 and 112. Namely, the first electrode 122 of the LED 120 and the second electrode 134 of the electrostatic protection device 130 are located on the same leadframe 112, and the second electrode 124 of the LED 120 and the first electrode 132 of the electrostatic protection device 130 are located on the same leadframe 114. In this way, the LED 120 is connected in anti-parallel to the electrostatic protection device 130, such that the LED 120 is ensured to be protected by the anti electrostatic protection function of the electrostatic protection device 130, so as to increase the service life of the LED package structure 100.

Referring to FIG. 2, the reflective member 116 of the present embodiment completely encapsulates the peripheral surface of the leadframes 112, 114, and only exposes the carrier surfaces 112a, 114a of the leadframes 112, 114, where a material of the reflective member 116 is, for example, epoxy resin or silicon resin, and reflectivity thereof is preferably greater than 90%, though the invention is not limited thereto. Although the leadframes 112, 114 of the present embodiment are encapsulated by the reflective member 116, the surface area of the upper surfaces 112′, 114′ of the leadframes 112, 114 is still far greater than the surface area of the bottom surface 117b of the cavity 117, which avails the LED 120 and the electrostatic protection device 130 to directly bridge the carrier surfaces 112a, 114a of the leadframes 112, 114, so as to achieve a better configuration space. Preferably, the carrier surfaces 112a, 114a of the leadframes 112, 114 are substantially aligned to the bottom surface 117b of the cavity 117, and lower surfaces 112b, 114b of the leadframes 112, 114 are substantially aligned to a lower surface 116b of the reflective member 116. A surface area of the upper surfaces 112′, 114′ of the leadframes 112, 114 is greater than a surface area of the lower surfaces 112b, 114b, which increases a bonding area of the reflective member 116 of the leadframes 112, 114 to enhance a whole bonding strength. It should be noticed that the contours of the carrier surfaces 112a, 114a are determined by a degree that the reflective member 116 encapsulates the leadframes 112, 114, so that the contours of the carrier surfaces 112a, 114a can be fabricated into various shapes according to user's design, for example, the four corners of the rectangle are rounded angels, which are not limited to the right angles shown in FIG. 1.

Since the carrier surfaces 112a, 114a of the leadframes 112, 114 of the present embodiment are substantially aligned to the bottom surfaces 117b of the cavity 117, a better configuration planeness is achieved when the LED 120 and the electrostatic protection device 130 are disposed on the leadframes 112, 114. Moreover, since the lower surfaces 112b, 114b of the leadframes 112, 114 are substantially aligned to the lower surface 116b of the reflective member 116, heat produced by the LED 120 can be quickly conducted out through the lower surfaces 112b, 114b of the leadframes 112, 114, so as to achieve a better heat dissipation effect of the LED package structure 100. Certainly, the lower surfaces 112b, 114b of the leadframes 112, 114 can also be directly connected to a heat dissipation member (not shown), so as to further improve the heat dissipation effect of the whole LED package structure 100. Alternatively, the lower surfaces 112b, 114b of the leadframes 112, 114 can also be directly connected to an external circuit (not shown), so as to effectively expand an application range of the LED package structure 100.

Moreover, the cavity 117 of the reflective member 116 of the present embodiment has an opening 117a, where the cavity 117 is tapered from the opening 117a towards the bottom surface 117b. Namely, a size of the opening 117a of the cavity 117 is greater than a size of the bottom surface 117b of the cavity 117, and according to such design, light emitted from the side of the LED 120 can be effectively reflected to concentrate a light shape. Certainly, in other embodiments that are not illustrated, the size of the opening of the cavity can be the same to the size of the bottom surface of the cavity, which is not limited by the invention. Since the carrier substrate 110 of the present embodiment has the reflective member 116, the light emitted by the LED 120 can be reflected by the reflective member 116 to achieve a better light emitting efficiency of the LED package structure 100. Moreover, since the LED 120 of the present embodiment is disposed inside the cavity 117, a package encapsulant (not shown) can be filled in the cavity 117 to effectively avoid the LED 120 from being invaded by water vapor and oxygen, so as to achieve better structural reliability.

Moreover, the LED 120 of the present embodiment is a flip chip LED, and the LED 120 and the leadframes 112, 114 of the carrier substrate 110 are electrically connected through eutectic bonding. In addition, the electrostatic protection device 130 of the present embodiment is a Zener diode, and the electrostatic protection device 130 and the leadframes 112, 114 of the carrier substrate 110 are electrically connected through eutectic bonding. Since both of the LED 120 and the electrostatic protection device 130 of the present embodiment adopt the eutectic bonding method to electrically connect the leadframes 112, 114 of the carrier substrate 110, a better bonding force is achieved between the LED 120 and the leadframes 112, 114 and between the electrostatic protection device 130 and the leadframes 112, 114, so as to improve the structural reliability of the LED package structure 100.

In summary, since the carrier substrate of the invention has the reflective member, the light emitted by the LED can be reflected by the reflective member, so as to achieve a good light emitting efficiency of the LED package structure of the invention. Moreover, based on the design of the leadframes of the invention, the LED and the electrostatic protection device can both bridge the leadframes of the carrier substrate and are connected in anti-parallel, so that the problem of the conventional technique that the Zener diode cannot implement the voltage regulation effect as the connection between the Zener diode and the metal wire is unstable to cause an open circuit is avoided. Namely, the LED package structure of the invention has better structural reliability and configuration space, and the LED is protected by an anti electrostatic protection function of the electrostatic protection device, so as to increase a service life of the LED package structure.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A light emitting diode package structure, comprising:
a carrier substrate, comprising two leadframes separated from each other and a reflective member, wherein the reflective member encapsulates the leadframes and exposes a carrier surface of each of the leadframes, the reflective member has a cavity, and a bottom surface of the cavity is aligned with the carrier surface of each of the leadframes;
a light emitting diode, disposed inside the cavity, and electrically bridging the leadframes; and
an electrostatic protection device, disposed inside the cavity, and electrically bridging the leadframes, wherein the light emitting diode is connected in anti-parallel to the electrostatic protection device.

2. The light emitting diode package structure as claimed in claim 1, wherein a surface area of an upper surface of the leadframes is greater than a surface area of the bottom surface of the cavity.

3. The light emitting diode package structure as claimed in claim 1, wherein the leadframes are separated from each other and spaced by a horizontal spacing distance, a contour of the carrier surface of each of the leadframes is a rectangle, and the horizontal spacing distance is smaller than a short side of the carrier surface.

4. The light emitting diode package structure as claimed in claim 1, wherein a contour of the carrier surface of each of the leadframes is a rectangle, and a vertical distance between one side of the light emitting diode and a short side of the corresponding carrier surface is 1.2-10 times of a width of the electrostatic protection device.

5. The light emitting diode package structure as claimed in claim 1, wherein a contour of the carrier surface of each of the leadframes is a rectangle, and a vertical distance between one side of the light emitting diode and a short side of the corresponding carrier surface is between 0.3 cm and 1 cm.

6. The light emitting diode package structure as claimed in claim 1, wherein a contour of the carrier surface of each of the leadframes is a rectangle, and an aspect ratio of the carrier surface of each of the leadframes is between 2 and 5.

7. The light emitting diode package structure as claimed in claim 1, wherein a contour of the carrier surface of each of the leadframes is a rectangle, and four corners of the carrier surface are right angles or rounded angles.

8. The light emitting diode package structure as claimed in claim 1, wherein the cavity has an opening, and the cavity is tapered from the opening towards the bottom surface.

9. The light emitting diode package structure as claimed in claim 1, wherein the light emitting diode and the leadframes of the carrier substrate are electrically connected through eutectic bonding.

10. The light emitting diode package structure as claimed in claim 1, wherein the light emitting diode is a flip chip light emitting diode.

11. The light emitting diode package structure as claimed in claim 1, wherein the electrostatic protection device is a Zener diode.

12. The light emitting diode package structure as claimed in claim 1, wherein the electrostatic protection device and the leadframes of the carrier substrate are electrically connected through eutectic bonding.

13. The light emitting diode package structure as claimed in claim 1, wherein the leadframes are symmetrically arranged.
